(19) United States
(12) Patent Application Publication
(10) Pub. No.: US 2025/0259865 A1
(43) Pub. Date: Aug. 14, 2025

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Kaoru YAMAMOTO, Toyama-shi (JP)

(73) Assignee: KOKUSAI ELECTRIC CORPORATION, Tokyo (JP)

(21) Appl. No.: 19/053,036

(22) Filed: Feb. 13, 2025

(30) Foreign Application Priority Data
Feb. 14, 2024 (JP) 2024-020704

(51) Int. Cl. H01L 21/67

(52) U.S. Cl. CPC H01L 21/67109; H01L 21/67017; H01L 21/67167; H01L 21/67248

(57) ABSTRACT

A technique includes: (a) a first process chamber in which processing of causing a temperature of a substrate to be a first temperature is performed; (b) a second process chamber whereby processing of causing a temperature of the substrate to be a second temperature higher than the first temperature is performed; (c) a transfer chamber formed in communication with the first process chamber and the second process chamber and including a transfer mechanism configured to transfer the substrate; (d) a temperature control mechanism configured to perform temperature control on a predetermined target in the transfer chamber; and (e) a controller capable of controlling the transfer mechanism and the temperature control mechanism to perform control with contents of transfer of the substrate between the first process chamber and the second process chamber and control with contents of the temperature control in accordance with the contents of transfer to be performed.

### CROSS-REFERENCE TO RELATED APPLICATION

This application is based upon and claims the benefit of priority from Japanese Patent Application No. 2024-020704, filed on Feb. 14, 2024, the entire contents of which are incorporated herein by reference.

### FIELD OF THE INVENTION

The present disclosure relates to a substrate processing apparatus, a method of processing a substrate, a method of manufacturing a semiconductor device, and a recording medium.

### DESCRIPTION OF THE RELATED ART

As one process among substrate processing processes (processes of manufacturing semiconductor devices), there may be a case where a substrate processing apparatus including a plurality of process chambers and a transfer chamber communicating with the process chambers is used to process a substrate.

### SUMMARY OF THE INVENTION

Some embodiments of the present disclosure provide a technique capable of reducing energy excessively consumed by a substrate processing apparatus.

According to an aspect of the present disclosure, a technique is provided, including:
a first process chamber in which processing of causing a temperature of a substrate to be a first temperature is performed;
a second process chamber in which processing of causing a temperature of the substrate to be a second temperature higher than the first temperature is performed;
a transfer chamber formed to be communicable with the first process chamber and the second process chamber and including a transfer mechanism configured to transfer the substrate;
a temperature control mechanism configured to perform temperature control on a predetermined target in the transfer chamber; and
a controller capable of controlling the transfer mechanism and the temperature control mechanism to perform control with contents of transfer of the substrate between the first process chamber and the second process chamber in the transfer chamber and control with contents of the temperature control in accordance with the contents of transfer to be performed.

### BRIEF DESCRIPTION OF THE DRAWINGS

FIG. 1 is a transverse cross-sectional view illustrating a configuration example of a substrate processing apparatus according to an embodiment.

FIG. 2 is a vertical cross-sectional view taken along line α-α′ of the substrate processing apparatus illustrated in FIG. 1.

FIG. 3 is a schematic configuration view of a chamber according to the embodiment.

FIG. 4 is a schematic configuration view of a gas supplier according to the embodiment.

FIG. 5 is a schematic configuration view of a controller illustrated in FIG. 1.

FIG. 6 is a flowchart of a substrate processing process in the substrate processing apparatus illustrated in FIG. 1.

FIG. 7 is a view for describing an output of temperature control.

### DETAILED DESCRIPTION

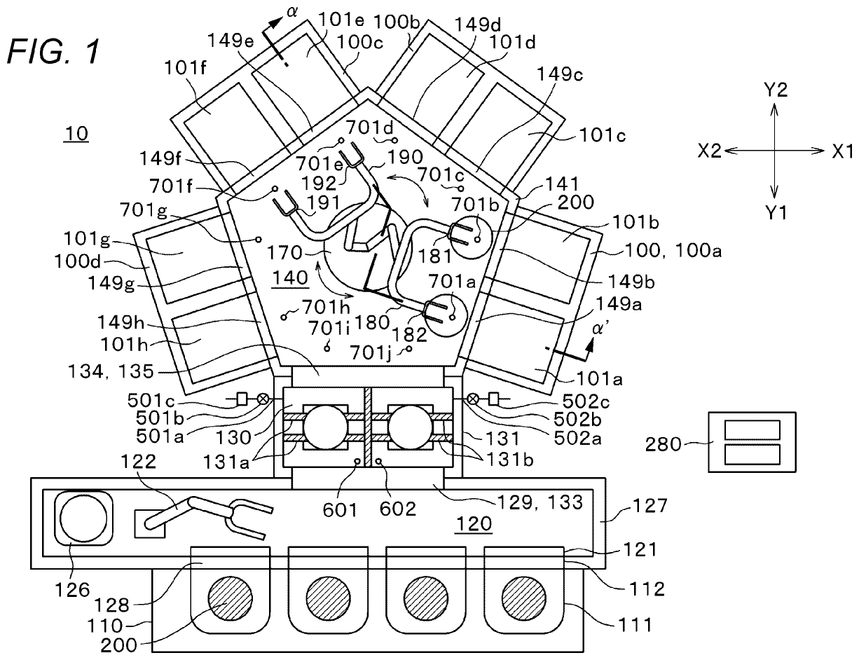

An aspect of the present disclosure will be described below mainly with reference to FIGS. 1 to 7. Note that the drawings used in below description are all schematic and thus, for example, the dimensional relationship between each constituent element and the ratio between each constituent element illustrated in the drawings do not necessarily coincide with realities. In addition, dimensional relationships between elements, ratios between elements, and the like do not necessarily coincide with each other between a plurality of drawings.

### (1) Configuration of Substrate Processing Apparatus

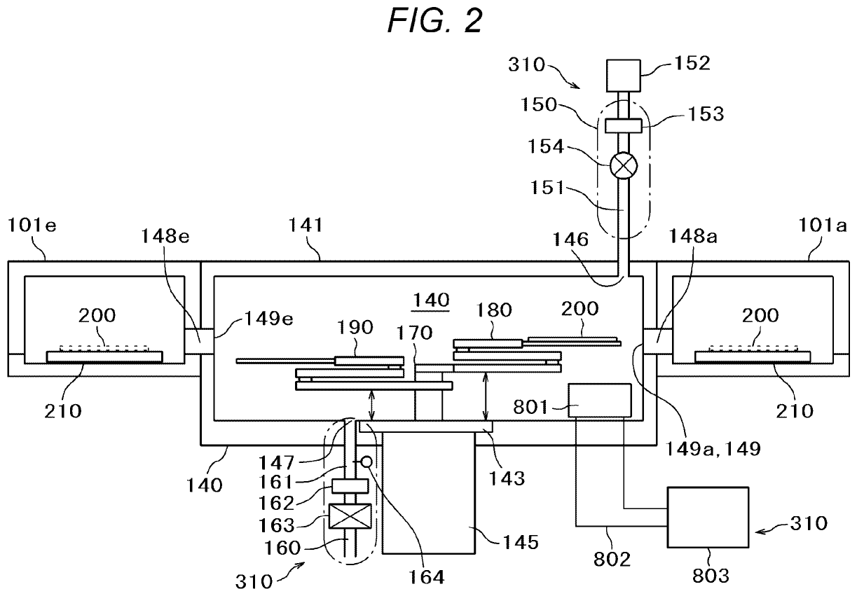

A schematic configuration of a substrate processing apparatus according to an embodiment will now be described herein with reference to FIGS. 1 and 2.

A substrate processing apparatus 10 processes wafers 200, and mainly includes an input-and-output (IO) stage 110, an atmospheric transfer chamber 120, a load lock chamber 130, a transfer chamber (transfer module or TM) 140, and process modules (PMs) 100. Next, each configuration will be specifically described. In below description, in FIG. 1, an X1 direction may be referred to as right, an X2 direction may be referred to as left, a Y1 direction may be referred to as front, and a Y2 direction may be referred to as back.

### (Atmospheric Transfer Chamber and IO Stage)

As illustrated in FIG. 1, the IO stage (load port) 110 is installed on a front side of the substrate processing apparatus 10. A plurality of pods 111 are equipped on the IO stage 110. The pods 111 are used as carriers for transferring the wafers 200 such as silicon (Si) substrates. In the pods 111, a plurality of the wafers 200 that are not processed and the wafers 200 that are processed are stored each in a horizontal posture.

Each of the pods 111 is provided with a cap 112, and is opened and closed by a pod opener 121. The pod opener 121 opens and closes the cap 112 of each of the pods 111 mounted on the IO stage 110, and opens and closes a substrate loading-and-unloading port of each of the pods 111. Each of the pods 111 is supplied to and discharged from the IO stage 110 by a non-illustrated in-process transfer device (rail guided vehicle (RGV)).

The IO stage 110 is adjacent to the atmospheric transfer chamber 120. The load lock chamber 130 described later is coupled to the atmospheric transfer chamber 120 on a surface different from a surface for the IO stage 110.

An atmospheric transfer robot 122 serving as a first transfer robot configured to transfer each of the wafers 200 is installed in the atmospheric transfer chamber 120. In addition, a device (hereinafter referred to as a pre-aligner) 126 configured to perform alignment of a notch or an orientation flat formed on each of the wafers 200 is installed on a left side of the atmospheric transfer chamber 120.

Loading-and-unloading ports 128 and the pod openers 121 are installed on a front side of a housing 127 of the atmospheric transfer chamber 120. The wafers 200 are transferred between the pods 111 and the atmospheric transfer chamber 120 via the loading-and-unloading ports 128.

A loading-and-unloading port 129 for loading and unloading the wafers 200 into and from the load lock chamber 130 is provided on a rear side of the housing 127 of the atmospheric transfer chamber 120. The loading-and-unloading port 129 is opened and closed by a gate valve (GV) 133. The wafers 200 are transferred between the atmospheric transfer chamber 120 and the load lock chamber 130 via the loading-and-unloading port 129.

### (Load Lock Chamber)

The load lock chamber 130 is adjacent to the atmospheric transfer chamber 120. As described later, the transfer chamber 140 is disposed on a surface different from a surface for the atmospheric transfer chamber 120 among surfaces of a housing 131 forming the load lock chamber 130.

A loading-and-unloading port 134 is provided on a side, which is adjacent to the transfer chamber 140, of the housing 131. The loading-and-unloading port 134 is opened and closed by a GV 135. The wafers 200 are transferred between the atmospheric transfer chamber 120 and the transfer chamber 140 via the loading-and-unloading port 134.

Furthermore, supports 131a, 131b on which the wafers 200 are to be placed are installed in the load lock chamber 130.

In addition, an inert gas supplier that supplies an inert gas serving as a cooling gas into the load lock chamber 130 and exhaust system 601, 602 configured to exhaust atmosphere air in the load lock chamber 130 are provided. The inert gas supplier includes gas supply pipes 501a, 502a, valves 501b, 502b, and mass flow controllers (MFCs) 501c, 502c serving as flow rate control devices (flow rate controllers), and is configured to be able to adjust a flow rate of the cooling gas to be supplied into the load lock chamber 130. The load lock chamber 130 also serves as a process chamber for performing processing of performing temperature control (cooling) of the wafers 200 to a predetermined temperature.

### (Transfer Chamber)

The substrate processing apparatus 10 includes the transfer chamber 140 serving as a transfer space in which each of the wafers 200 is to be transferred. A depressurized state or a vacuum state may be maintained inside the transfer chamber 140. A housing 141 forming the transfer chamber 140 is formed into a pentagonal shape in plan view, and the load lock chamber 130 and PMs 100a to 100d in which each of the wafers 200 is to be processed are coupled to respective sides of the pentagonal shape. As illustrated in FIG. 2, a transfer robot 170 serving as a transfer mechanism configured to transfer (convey) each of the wafers 200 is installed at a substantially center of the transfer chamber 140 via a flange 143 serving as a base. Note that, although an example in which the transfer chamber 140 has a pentagonal shape is illustrated in here, the transfer chamber may have a polygonal shape such as a quadrangle shape or a hexagonal shape. The transfer chamber 140 is provided with a heat transfer gas supplier 150, a gas exhaust system 160, and a heat medium supplier, which serve as an example of a temperature control mechanism 310 configured to perform temperature control on a predetermined target in the transfer chamber 140.

As illustrated in FIG. 2, the transfer robot 170 installed in the transfer chamber 140 is configured to be lifted and lowered while maintaining airtightness of the TM 140 by an elevator 145 and the flange 143. The elevator 145 is configured to independently lift and lower two arms 180 and 190 that the transfer robot 170 includes. In addition, each of the two arms 180 and 190 is provided with each of tweezers 181, 182, 191, 192, and is configured to be able to simultaneously transfer two of the wafers 200 by one arm.

The housing 141 is provided with a heat transfer gas supply hole 146 for supplying a heat transfer gas into the housing 141. The heat transfer gas supply hole 146 is provided with a heat transfer gas supply pipe 151. The heat transfer gas supply pipe 151 is provided with, in order from upstream, a heat transfer gas source 152, a mass flow controller (MFC) 153, and a valve 154 for controlling a supply amount of the heat transfer gas to be supplied into the housing 141.

The heat transfer gas supplier 150 in the transfer chamber 140 mainly includes the heat transfer gas supply pipe 151, the MFC 153, and the valve 154. Note that the heat transfer gas supplier 150 may include the heat transfer gas source 152 and the heat transfer gas supply hole 146.

The housing 141 is provided with an exhaust hole 147 for exhausting atmosphere air in the housing 141. The exhaust hole 147 is provided with an exhaust pipe 161. The exhaust pipe 161 is provided with, in order from upstream, a pressure sensor 164 serving as a pressure detector configured to detect pressure in the transfer chamber 140, an auto-pressure controller (APC) 162 serving as a pressure control device, and a vacuum pump 163.

The exhaust pipe 161 and the APC 162 mainly form the gas exhaust system 160 in the transfer chamber 140. Note that the exhaust system 160 may include the pressure sensor 164, the vacuum pump 163, and the exhaust hole 147.

At least one of the heat transfer gas supplier 150 and the gas exhaust system 160 controls the pressure in the transfer chamber 140. Note that at least one of the heat transfer gas supplier 150 and the gas exhaust system 160 may control the pressure in the transfer chamber 140 based on measurement data by the pressure sensor 164.

As illustrated in FIG. 1, the PMs 100a, 100b, 100c, 100d configured to perform desired processing on the wafers 200 are coupled to sides where the load lock chamber 130 is not installed among five side walls of the housing 141. One or more of the PMs 100a, 100b, 100c, 100d may be hereinafter referred to as the PMs 100.

The PMs 100a, 100b, 100c, 100d are respectively provided with chambers 101 serving as a configuration of the substrate processing apparatus. Note herein that the chambers 101 are one or more of chambers 101a to 101h. Specifically, the PM 100a is provided with the chambers 101a, 101b. The PM 100b is provided with the chambers 101c, 101d. The PM 100c is provided with the chambers 101e, 101f. The PM 100d is provided with the chambers 101g, 101h.

Loading-and-unloading ports 148 are provided on the walls facing the chambers 101, respectively, among the side walls of the housing 141. Note herein that the loading-and-unloading ports 148 are one or more of loading-and-unloading ports 148a to 148h. For example, as illustrated in FIG. 2, the loading-and-unloading port 148a is provided on one of the side walls of the housing 141, which faces the chamber 101a. Similarly, the loading-and-unloading ports 148b to 148h are provided on the side walls of the housing 141, which face the chambers 101b to 101h, respectively.

GVs 149a to 149h are provided for the chambers 101, respectively. Specifically, the GV 149a is provided between the chamber 101a and the TM 140. Similarly, the GVs 149b to 149h are provided between the chambers 101b to 101h and the TM140, respectively. One or more of the GVs 149a to 149h may be referred to as the GVs 149.

The loading-and-unloading ports 148a to 148h are opened and closed by the GVs 149, respectively. The wafers 200 are transferred between the transfer chamber 140 and the chambers 101 through the loading-and-unloading ports 148. That is, the transfer chamber 140 is formed to be communicable with the chambers 101a to 101h.

In addition, temperature sensors (temperature measurers) 701a, 701b, 701c, 701d, 701e, 701f, 701g, 701h, 701i, 701j configured to measure temperatures of the wafers 200 may be provided in the transfer chamber 140 and in front of the GVs 135, 149, respectively. The temperature sensors are, for example, radiation thermometers. As the temperature sensors are provided, it is possible to measure the temperatures of the wafers 200 being transferred. The temperature sensors 701a to 701j are, when not distinguished from each other, collectively referred to as the temperature sensors 701.

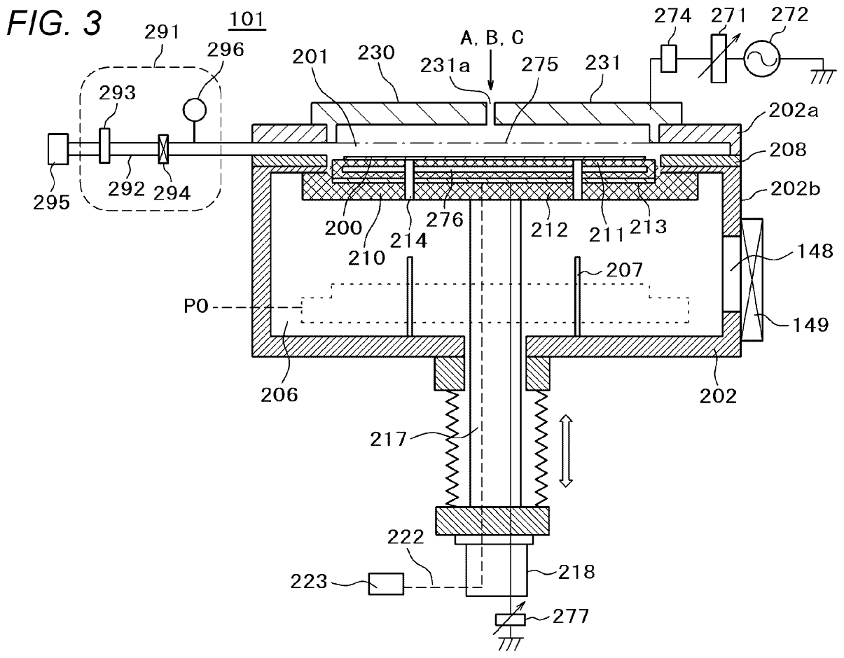

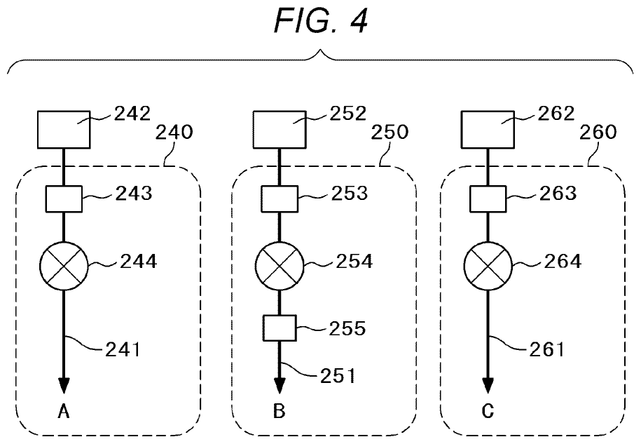

Next, the chambers 101a to 101h will now be described herein with reference to FIGS. 3 and 4. Since the chambers 101a to 101h have similar or identical configurations to each other, each of the chambers will be hereinafter described as one chamber 101. Each of the chambers 101 is formed to be able to perform a plurality of types of processing. Details will be described below.

The chamber 101 includes a container 202. The container 202 is configured as, for example, a hermetically sealed flat container having a circular transverse cross section. In addition, the container 202 includes, for example, a metal material such as aluminum (Al) or stainless steel (SUS). The container 202 is formed with a process chamber 201 forming a process space for processing the wafer 200 and a transfer chamber 206 including a transfer space through which the wafer 200 passes when the wafer 200 is to be transferred into the process chamber 201. The container 202 includes an upper container 202a and a lower container 202b. A partition 208 is provided between the upper container 202a and the lower container 202b.

The loading-and-unloading port 148 adjacent to the GV 149 is provided on a side surface of the lower container 202b, and the wafer 200 moves between the container and the transfer chamber 140 via the loading-and-unloading port 148. At a bottom of the lower container 202b, a plurality of lift pins 207 are provided.

In the process chamber 201, a substrate support 210 configured to support the wafer 200 is disposed. The substrate support 210 mainly includes a substrate mounting surface 211 on which the wafer 200 is to be mounted, a substrate mounting table 212 including the substrate mounting surface 211 on its surface, and a heater 213 provided in the substrate mounting table 212. In the substrate mounting table 212, through-holes 214 through which the lift pins 207 pass are provided at positions corresponding to the lift pins 207, respectively. In addition, the substrate mounting table 212 may be provided with a bias electrode 276 configured to apply a bias to the wafer 200 and the process chamber 201.

Wiring 222 for supplying electric power is coupled to the heater 213. The wiring 222 is coupled to a heater controller 223. The heater controller 223 is electrically coupled to a controller 280. The controller 280 is configured to control the heater controller 223 to allow the heater 213 to operate. In addition, the bias electrode 276 is coupled to a bias adjuster 277, and it is configured that the bias is adjustable by the bias adjuster 277.

The substrate mounting table 212 is supported by a shaft 217. The shaft 217 passes through a bottom of the container 202 and is further coupled to a lifter 218 outside the container 202. As the lifter 218 is caused to operate to lift and lower the shaft 217 and the substrate mounting table 212, the substrate mounting table 212 is able to lift and lower the wafer 200 mounted on the substrate mounting surface 211.

The process chamber 201 includes, for example, a buffer structure 230 described later and the substrate mounting table 212. Note that it is sufficient that the process chamber 201 be only able to secure the process space for processing the wafer 200, and may be formed based on another structure.

When the wafer 200 is to be transferred, the substrate mounting surface 211 of the substrate mounting table 212 lowers to a transfer position P0 facing the loading-and-unloading port 148, and, when the wafer 200 is to be processed, the wafer 200 is lifted to a process position in the process chamber 201, as illustrated in FIG. 3.

The buffer structure 230 for allowing a gas to be diffused is provided to an upper portion (upstream side) of the process chamber 201. The buffer structure 230 mainly includes a lid 231. A first gas supplier 240, a second gas supplier 250, and a third gas supplier 260, which will be described later, are coupled to a gas introduction hole 231a provided in the lid 231. In accordance with processing performed in each of the process chambers 201, coupling between a part of a gas supply system and the gas introduction hole 231a may be omitted, and an additional gas supplier may be further coupled to the gas introduction hole 231a. Although the gas introduction hole 231a illustrated in FIG. 3 is only one, a gas introduction hole may be provided for each of the gas suppliers.

Next, an exhaust system 291 will now be described herein. An exhaust pipe 292 communicates with the process chamber 201. The exhaust pipe 292 is coupled to the upper container 202a to communicate with the process chamber 201. The exhaust pipe 292 is provided with, in order from upstream, a pressure sensor 296 serving as a pressure detector configured to detect pressure in the process chamber 201 and an APC 293 serving as a pressure control device configured to control the pressure in the process chamber 201 to predetermined pressure based on data of the pressure sensor 296. The APC 293 including a valve body (not illustrated) in which its degree of opening is adjustable regulates conductance of the exhaust pipe 292 in accordance with an instruction from the controller 280. In addition, a valve 294 is provided on an upstream side of the APC 293 in the exhaust pipe 292. The exhaust pipe 292, the valve 294, and the APC 293 are collectively referred to as the exhaust system.

Furthermore, a vacuum pump 295 is provided downstream of the exhaust pipe 292. The vacuum pump 295 exhausts atmosphere air in the process chamber 201 via the exhaust pipe 292.

A matcher 271 and a high frequency power source 272 are configured and coupled to an electrode 275 serving as an activator (plasma generator), making it possible to supply an electromagnetic wave (high frequency electric power or a microwave). As a result, it is possible to activate a gas supplied into the process chamber 201. In addition, the electrode 275 is configured to be able to generate capacitive coupling type plasma. Specifically, the electrode 275 is formed in a plate shape to have electric conductivity, and is configured to be supported by the upper container 202a. The activator includes at least the electrode 275, the matcher 271, and the high frequency power source 272. Note that the activator may include an impedance meter 274. Note that the impedance meter 274 may be provided between the electrode 275 and the high frequency power source 272. Providing the impedance meter 274 makes it possible to perform feedback control for the matcher 271 and the high frequency power source 272 based on measured impedance.

Next, the gas supplier configured to supply a gas into the process chamber 201 will now be described herein with reference to FIG. 4.

A first gas supply pipe 241 is provided with, in order in an upstream direction, a first gas source 242 configured to supply a first gas, an MFC 243, and a valve 244 that is an opening-and-closing valve. The first gas is an example of a process gas in the present disclosure. The first gas supply pipe 241, the MFC 243, and the valve 244 mainly form the first gas supplier 240. The first gas supplier 240 may include the first gas source 242 and the gas introduction hole 231a.

A second gas supply pipe 251 is provided with, in order in the upstream direction, a second gas source 252 configured to supply a second gas, an MFC 253, and a valve 254 that is an opening-and-closing valve. The second gas is an example of a process gas in the present disclosure. The second gas supply pipe 251 may be provided with a remote plasma unit (RPU) 255. The RPU 255 brings the second gas passing through the second gas supply pipe 251 into a plasma state. The second gas supply pipe 251, the MFC 253, and the valve 254 mainly form the second gas supplier 250. The second gas supplier 250 may include the RPU 255. In addition, the second gas supplier 250 may include the second gas source 252 and the gas introduction hole 231a.

A third gas supply pipe 261 is provided with, in order in the upstream direction, a third gas source 262 configured to supply a third gas, an MFC 263, and a valve 264 that is an opening-and-closing valve. The third gas is, for example, an inert gas. The third gas may be a purge gas used to perform purging inside the process chamber 201. The third gas supply pipe 261, the MFC 263, and the valve 264 mainly form the third gas supplier 260. The third gas supplier 260 may include the third gas source 262 and the gas introduction hole 231a.

### (Controller)

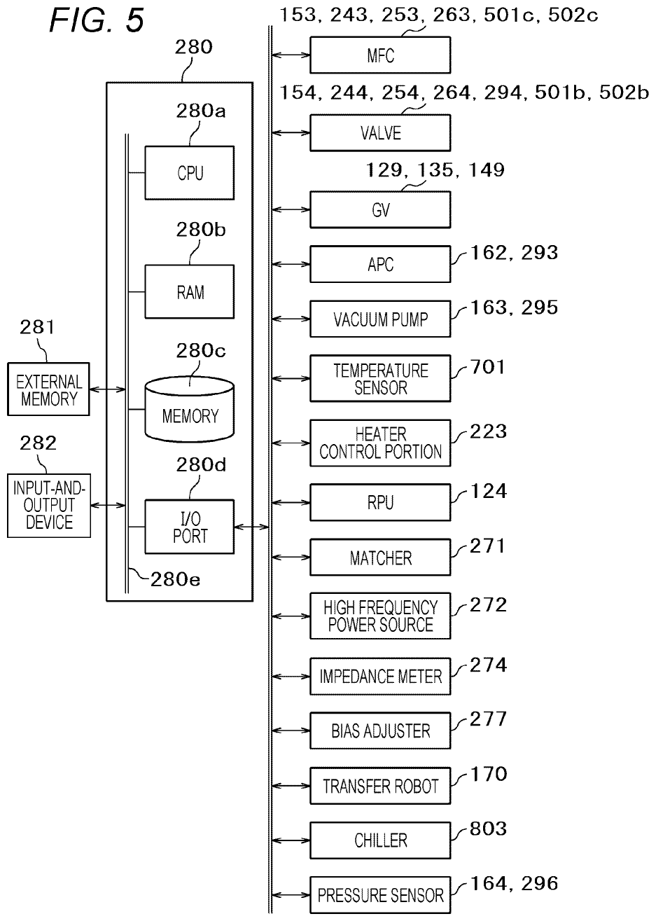

The substrate processing apparatus 10 illustrated in FIG. 1 includes the controller 280 configured to control operation of each component of the substrate processing apparatus 10. Next, the controller 280 will be described herein with reference to FIG. 5.

The controller 280 is configured to serve as a computer including a central processing unit (CPU) 280a, a random access memory (RAM) 280b, a memory 280c, and an input-and-output (I/O) port 280d. The RAM 280b, the memory 280c, and the I/O port 280d are configured to be able to exchange data with the CPU 280a via an internal bus 280e. An input-and-output device 282 formed as a touch panel and an external memory 281 are, for example, formed to be able to be coupled to the controller 280.

The memory 280c includes, for example, a flash memory and a hard disk drive (HDD). The memory 280c stores, in a readable manner, for example, a control program for controlling operation of the substrate processing apparatus, a process recipe describing procedures and conditions for substrate processing described later, and calculation data and processing data generated until a process recipe used for performing processing on the wafer 200 is set. Note that a process recipe is a combination of those causing the controller 280 to execute each step in a substrate processing process described later to acquire a certain result, and functions as a program. Hereinafter, for example, the process recipe, the control program, and the like will also be collectively and simply referred to as a program. Note that, in the present specification, the term “program” may include only a process recipe alone, only a control program alone, or both of them. In addition, the RAM 280b is configured to serve as a memory region (work area) in which a program, calculation data, and processing data, for example, read by the CPU 280a are temporarily stored.

The I/O port 280d is coupled to, for example, the GVs 133, 135, 149, the heater controller 223, the APCs 162, 293, the vacuum pumps 163, 295, the pressure sensors 164, 296, the matcher 271, the high frequency power source 272, the MFCs 153, 243, 253, 263, 501c, 502c, the valves 154, 244, 254, 264, 294, 501b, 502b, the RPU 255, the bias adjuster 277, the transfer robot 170, and a chiller 803. In addition, for example, it may also be coupled to the impedance meter 274.

The CPU 280a serving as a calculator is configured to read and execute a control program from the memory 280c, and to read a process recipe from the memory 280c in response to input of an operation command from the input-and-output device 282, for example. Then, the CPU 280a is configured to control, in accordance with contents of the read process recipe, for example, opening-and-closing operation of the GVs 149, operation of the heater controller 223, pressure adjustment operation of the APCs 162, 293 based on the pressure sensors 164, 296, on-and-off control of the vacuum pumps 163, 295, gas flow rate control operation using the MFCs 153, 243, 253, 263, 501c, 502c, gas activation operation of the RPU 255, gas on-and-off control using the valves 154, 244, 254, 264, 294, 501b, 502b, matching operation of electric power of the matcher 271, electric power control of the high frequency power source 272, control operation of the bias adjuster 277, matching operation of the matcher 271 based on measurement data measured by the impedance meter 274, electric power control operation of the high frequency power source 272, and transfer operation of the transfer robot 170. When each component is to be controlled, the CPU 280a performs control by transmitting and receiving control information in accordance with the contents of the process recipe.

Note that the controller 280 is not limited to be configured as a dedicated computer, and may be configured as a general-purpose computer. For example, preparing the external memory (e.g., a magnetic tape, a magnetic disk, such as a flexible disk or hard disk, an optical disc, such as a compact disc (CD) or digital versatile disc (DVD), a magneto-optical disc called MO, or a semiconductor memory, such as a universal serial bus (USB) memory or memory card) 281 storing the program described above and then using the external memory 281 to install the program on a general-purpose computer make it possible to achieve the controller 280 according to the present embodiment. Note that the memory 280c and the external memory 281 are configured to each serve as a computer-readable recording medium. Hereinafter, these will also be collectively and simply referred to as a recording medium. Note that, in the present specification, the term “recording medium” may include only the memory 280c alone, only the external memory 281 alone, or both of the memories.

### (2) Process of Manufacturing Semiconductor Device

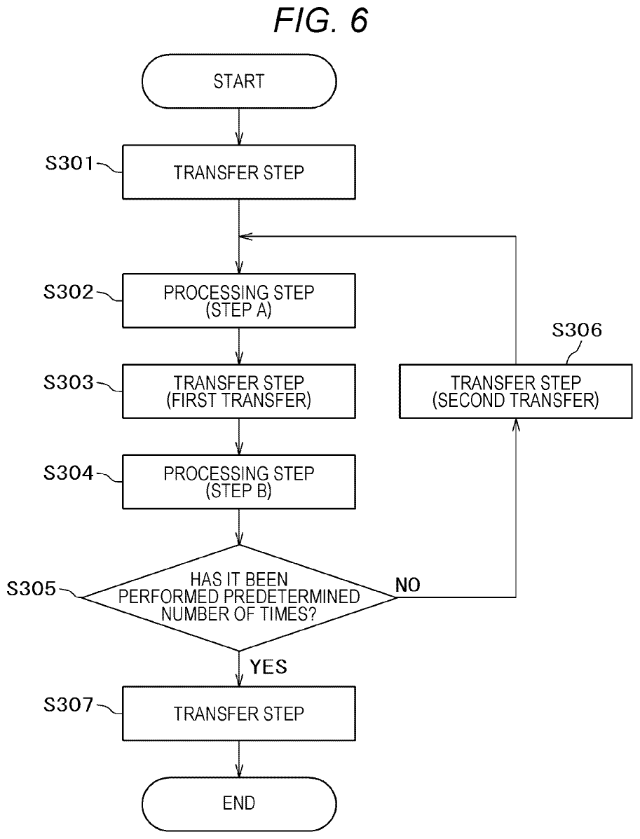

Next, as one process among processes of manufacturing semiconductor devices, an example of processing of the wafer 200 using a plurality of chambers in which processing temperatures differ from each other will be described herein with reference to FIG. 6. Note that one process among the manufacturing processes is performed in the substrate processing apparatus 10 described above. Note that, the controller 280 controls operation of each component to perform processes in below description.

The term “wafer” used in the present specification may mean the wafer itself, or a laminate of the wafer and a predetermined layer or film formed on the surface the wafer. The term “surface of the wafer” used in the present specification may mean the surface of the wafer itself or the surface of a predetermined layer and the like formed on the wafer. The term “forming a predetermined layer on the wafer” in the present specification may mean that a predetermined layer is directly formed on the surface of the wafer itself or that a predetermined layer is formed on a layer and the like formed on the wafer. In a case where the term “substrate” is used in this specification, this is a synonym of the term “wafer”.

In the present disclosure, “causing a substrate in a certain process chamber A to move to another process chamber B” means “causing a substrate to be transferred from the process chamber A to the process chamber B”. In addition, when the process chamber A and the process chamber B are not specified, “transferring of a substrate from the process chamber A to the process chamber B” may be simply referred to as “transferring of the substrate” or “transferring”. In below description, a point in time at which the transfer mechanism supports a substrate in the process chamber A is referred to as “start of transfer” and a point in time at which the transfer mechanism places the substrate in the process chamber B is referred to as “end of transfer”. Note that a period of time during transfer (that is, a period of time from the start of transfer to the end of transfer) may include a period of time during which the substrate is not moved. In addition, a period of time during transfer may include a period of time during which the transfer mechanism does not support a substrate. In addition, a substrate may be transferred by a plurality of transfer mechanisms.

An example of the substrate processing process using the PM 100a and the PM 100b will now be described herein. Note herein that an example will now be described herein, in which processing of causing a temperature of the wafer 200 to be a first temperature is performed in each of the process chambers 201 in the chambers 101a, 101b of the PM 100a serving as a first process chamber and processing of causing a temperature of the wafer 200 to be a second temperature higher than the first temperature is performed in each of the process chambers 201 in the chambers 101c, 101d of the PM 100b serving as a second process chamber.

### (Transfer Step S301)

In transfer step S301, the atmospheric transfer robot 122 picks up and loads the wafer 200 in the pod 111 on the IO stage 110 into the load lock chamber 130, and places the wafer 200 on the support 131a, 131b. After that, purging in the load lock chamber 130 is performed using the inert gas supplier and the exhaust system 601, 602 to allow pressure in the load lock chamber 130 to reach substantially identical pressure to pressure in the transfer chamber 140. Next, the transfer robot 170 uses the arm 180 or 190 to load the wafer 200 from the load lock chamber 130 into the transfer chamber 140. Next, the transfer robot 170 loads (transfers) the wafer 200 held by the arm 180 or 190 from the transfer chamber 140 into the process chamber 201 of the PM 100a.

### (Processing Step (Step A) S302)

In processing step S302, processing involving at least one of a chemical reaction, supply of a gas activated by plasma, and adsorption (chemical adsorption and/or physical adsorption) of a process gas other than an inert gas is performed on at least a part of the wafer 200.

For example, in step A in processing step S303, in a state where the wafer 200 is heated to the first temperature (the temperature of wafer 200 is caused to the first temperature) in accordance with a process recipe, the first gas supplier 240 and the third gas supplier 260 in the PM 100a are controlled to supply the first gas and the third gas to the process chamber 201. In addition, the exhaust system 291 is controlled to allow air in the process chamber 201 to be exhausted. Thus, the processing is performed on the wafer 200.

### (Transfer Step (First Transfer) S303)

After the wafer 200 has undergone the predetermined processing, the transfer robot 170 uses the arm 180 or 190 to bring out the wafer 200 from the process chamber 201 of the PM 100a into the transfer chamber 140. Next, the transfer robot 170 loads (transfers) the wafer 200 held by the arm 180 or 190 from the transfer chamber 140 into the process chamber 201 of the PM 100b. Note herein that transferring of the wafer 200 from the process chamber 201 of the PM 100a into the process chamber 201 of the PM 100b is referred to as first transfer.

During the transfer, the temperature control mechanism 310 performs temperature control (referred in here as first temperature control 311) on a predetermined target in accordance with contents of the transfer (referred in here as contents of the first transfer). The first temperature control 311 will be described later. The predetermined target is, for example, at least one of the wafer 200, a gas in the transfer chamber 140, and an object (for example, the arms 180, 190 of the transfer robot 170) in the transfer chamber 140.

### (Processing Step (Step B) S304)

In processing step S304, processing involving at least one of a chemical reaction, supply of a gas activated by plasma, and adsorption (chemical adsorption and/or physical adsorption) of a process gas other than an inert gas is performed on at least a part of the wafer 200.

For example, in step B in processing step S304, in a state where the wafer 200 is heated to the second temperature (the temperature of wafer 200 is caused to the second temperature) in accordance with a process recipe, the second gas supplier 250 and the third gas supplier 260 in the PM 100b are controlled to supply the second gas and the third gas to the process chamber 201. In addition, the exhaust system 291 is controlled to allow air in the process chamber 201 to be exhausted. In addition, the RPU 255 may be used or high frequency electric power may be supplied to the bias electrode 276 to supply a gas in a plasma state into the process chamber 201. Thus, the processing is performed on the wafer 200.

### (Determination S305)

In here, it is determined whether or not the processing of step A and step B has been performed on the wafer 200 a predetermined number of times. When it is determined that the processing has not yet been performed the predetermined number of times, transfer step S306 is performed. When it is determined that the processing has been performed the predetermined number of times, transfer step S307 is performed.

### (Transfer Step (Second Transfer) S306)

After the wafer 200 has undergone the predetermined processing in the process chamber 201 of the PM 100b, the transfer robot 170 uses the arm 180 or 190 to bring out the wafer 200 from the process chamber 201 of the PM 100b into the transfer chamber 140. Next, the transfer robot 170 loads (transfers) the wafer 200 held by the arm 180 or 190 from the transfer chamber 140 into the process chamber 201 of the PM 100a. Note herein that transferring of the wafer 200 from the process chamber 201 of the PM 100b to the process chamber 201 of the PM 100a is referred to as second transfer.

During the transfer, the temperature control mechanism 310 performs temperature control (referred in here as second temperature control 312) on a predetermined target in accordance with contents of the transfer (referred in here as contents of the second transfer). The second temperature control 312 will be described later.

### (Transfer Step S307)

As the processing in the plurality of chambers ends, the transfer robot 170 uses the arm 180 or 190 to transfer the processed wafer 200 unloaded from the PM 100b into the load lock chamber 130, allowing the wafer 200 to be transferred to the support 131a, 131b in the load lock chamber 130. After that, the inert gas supplier and the exhaust system 601, 602 allow pressure in the load lock chamber 130 to reach substantially identical pressure to atmospheric pressure. At this time, an inert gas supplied into the load lock chamber 130 may cool the wafer 200. Next, the atmospheric transfer robot 122 picks up the wafer 200 from the support 131a, 131b in the load lock chamber 130, unloads the wafer into the atmospheric transfer chamber 120, and, further, stores the wafer in the pod 111.

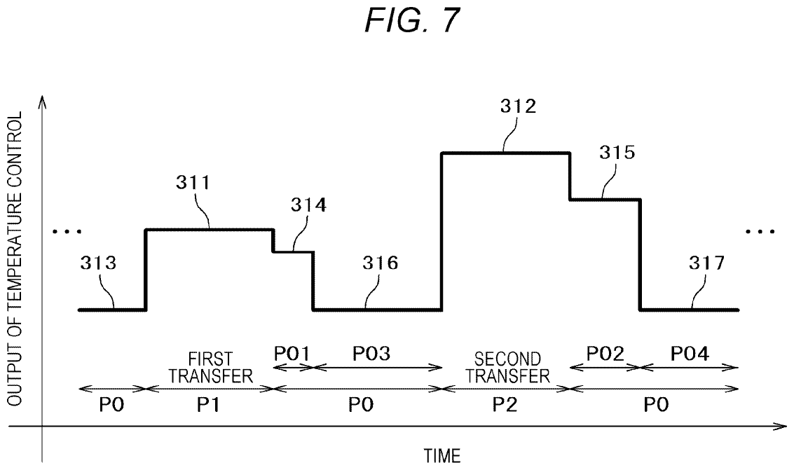

Next, a relationship between temperature control and transfer will now be described herein with reference to FIG. 7. FIG. 7 schematically illustrates transition of an output of temperature control when periods of time during which there is transfer in progress and periods of time during which there is no transfer in progress alternately appear. Note herein that contents of transfer in the present disclosure include presence or absence of transfer in progress. In addition, in the present disclosure, energy required for operation of the temperature control mechanism 310 in controlling of the temperature of a predetermined target may be referred to as an output of temperature control. That is, as an output of temperature control increases, energy to be consumed by the temperature control mechanism 310 increases, allowing the temperature of the predetermined target to easily change. In addition, an increase in energy to be consumed refers to, for example, an increase in consumption of electric power by the temperature control mechanism 310 and an increase in an amount of a substance to be consumed in accordance with each temperature control.

A period of time during which there is transfer in progress refers to a period of time P1 during which at least one of the arms 180 and 190 holds the wafer 200, and a period of time P0 during which there is no transfer in progress refers to a period of time during which neither of the arms 180 and 190 holds the wafer 200. In addition to the period of time P1 of the first transfer and a period of time P2 of the second transfer, the periods of time during which there is transfer in progress may include a period of time during which the arm 180, 190 loads the wafer 200 from the load lock chamber 130 into the transfer chamber 140 and a period of time during which the arm 180, 190 unloads the wafer 200 from the transfer chamber 140 into the load lock chamber 130.

The contents of temperature control performed by the temperature control mechanism 310 are controlled in accordance with the contents of transfer. The contents of temperature control include, for example, at least one of the first temperature control 311, the second temperature control 312, third temperature control 313, fourth temperature control 314, fifth temperature control 315, sixth temperature control 316, and seventh temperature control 317, as described below.

The first temperature control 311 is performed during the first transfer. The second temperature control 312 is performed during the second transfer at an output different from an output of the first temperature control 311. Note that the first temperature control may be performed in at least a part of the first transfer in progress. In addition, the second temperature control may be performed in at least a part of the second transfer in progress.

Processing of causing a temperature of the wafer 200 to the second temperature is performed before the second transfer, and processing of causing a temperature of the wafer 200 to the first temperature lower than the second temperature is performed after the second transfer. That is, after the second transfer, the wafer 200 is cooled. Note herein that, when the temperature control mechanism 310 cools a predetermined target, performing the second temperature control 312 at an output higher than an output of the first temperature control 311 makes it possible to shorten a period of time required for the processing of causing a temperature of the wafer 200 to the first temperature in the process chamber 201. Therefore, it is possible to achieve an improvement in a number of the wafers 200 that are able to be processed per unit time (to improve a throughput). In addition, performing the second temperature control 312 at an output higher than an output of the first temperature control 311 makes it possible to suppress damage on a part of the transfer robot 170 due to heat from the wafer 200.

On the other hand, processing of causing a temperature of the wafer 200 to the first temperature is performed after the first transfer, and processing of causing a temperature of the wafer 200 to be the second temperature higher than the first temperature is performed after the first transfer. That is, after the first transfer, the wafer 200 is heated. Note herein that performing control at an output lower than an output of the second temperature control 312 makes it possible to shorten a period of time required for the processing of causing a temperature of the wafer 200 to be the second temperature in the process chamber 201, and to reduce energy to be consumed excessively by the temperature control mechanism 310. In addition, the temperature of the wafer 200 that is subject to transfer during the first transfer is lower than the temperature of the wafer 200 during the second transfer, and a risk of damage to the transfer robot 170 due to heat from the wafer 200 is relatively low. Therefore, it is possible to perform the second temperature control 312 at an output lower than an output of the first temperature control 311, making it possible to reduce energy to be consumed by the temperature control mechanism 310 for cooling the transfer robot 170.

Similarly, when the temperature control mechanism 310 heats a predetermined target, the second temperature control 312 may be performed at an output lower than an output of the first temperature control 311. In addition, the first temperature control 311 may be performed at an output higher than an output of the second temperature control 312. As a result, it is possible to acquire at least one effect among reducing energy to be consumed by the temperature control mechanism 310 and improving a throughput.

As a result, performing the first temperature control 311 and the second temperature control 312 at outputs different from each other makes it possible to acquire at least one effect among reducing energy to be consumed by the temperature control mechanism 310 and improving a throughput.

The third temperature control 313 is performed during the period of time P0 during which there is no transfer in progress at an output lower than an output of the first temperature control 311. Note that the third temperature control may be performed in at least a part of the period of time P0 during which there is no transfer in progress. As a result, it is possible to reduce energy to be consumed by the temperature control mechanism 310.

The fourth temperature control 314 is performed after the first transfer and during a period of time P01 during which there is no transfer in progress. The fifth temperature control 315 is performed during a period of time P02 after the second transfer and during which there is no transfer in progress, and is performed at an output higher than an output of the fourth temperature control 314. Note that the fourth temperature control 314 and the fifth temperature control 315 may be performed respectively in at least a part of each of the periods of time P01 and P02.

The temperature of the wafer 200 that is subject to transfer during the first transfer is lower than the temperature of the wafer 200 that is subject to transfer during the second transfer. Therefore, during the period of time P02, the risk of damage to the transfer robot 170 due to heat from the wafer 200 is lower than the risk of damage during the period of time P01. Therefore, performing the fifth temperature control 315 at an output lower than an output of the fourth temperature control 314 makes it possible to reduce energy to be consumed by the temperature control mechanism 310. In addition, the fifth temperature control 315 is performed at an output higher than an output of the fourth temperature control 314. As a result, it is possible to efficiently lower the temperature of an object in the transfer chamber 140, making it possible to suppress malfunction of various mechanisms due to an increase in temperature. Note herein that it is preferable that the fifth temperature control 315 be performed longer than the fourth temperature control 314. As a result, effects of reducing energy to be consumed by the temperature control mechanism 310 and suppressing malfunction of various mechanisms are further easily acquired.

The sixth temperature control 316 is performed after the fourth temperature control 314 in at least a part of a period of time P03 during which there is no transfer in progress, and is performed at an output higher than an output of the fourth temperature control 314. The seventh temperature control 317 is performed after the fifth temperature control 315 in at least a part of a period of time P04 during which there is no transfer in progress, and is performed at an output lower than an output of the fifth temperature control 315. As a result, it is possible to reduce energy to be consumed by the temperature control mechanism 310 after the temperature of a target is lowered through the fourth temperature control 314 and the fifth temperature control 315.

The contents of transfer may include at least one of a path along which the wafer 200 moves in the transfer chamber 140 during transfer and a period of time required for the transfer. For example, there are differences in path and period of time required for transfer between a case of transfer from the PM 100a to the PM 100b and a case of transfer from the PM 100a to the PM 100c. When a purpose of temperature control is cooling, for example, and when there are or is a longer path of transfer and/or a longer period of time required for the transfer, an output of the temperature control mechanism 310 may be further increased. As a result, it is possible to suppress malfunction of various mechanisms due to an increase in temperature. In addition, when there are or is a shorter path of transfer and/or a shorter period of time required for the transfer, the output of the temperature control mechanism 310 may be further reduced. As a result, it is possible to reduce energy to be consumed by the temperature control mechanism 310. In addition, when there are or is a shorter path of transfer and/or a shorter period of time required for the transfer, the output of the temperature control mechanism 310 may be further increased. As a result, it is possible to efficiently cool the wafer 200 in the transfer chamber 140.

The temperature control mechanism 310 may control the contents of temperature control in accordance with the temperature of a predetermined target (for example, the wafer 200). For example, temperature data is acquired while the processed wafer 200 is transferred from the process chamber 201 of the PM 100a or the PM 100b to the process chamber 201 of the PM 100b or the PM 100a via the transfer chamber 140. To acquire temperature data, it is acquired, for example, by measuring the temperature of the wafer 200 with at least one of the temperature sensors 701a, 701b, 701c, 701d, 701e, 701f, 701g, 701h, 701i, 701j provided in the transfer chamber 140.

For example, an amount of a heat transfer gas to be supplied to the transfer chamber 140 by the heat transfer gas supplier 150 is controlled based on the acquired temperature data of the wafer 200 to allow the wafer 200 to undergo temperature control (for example, for cooling). As a result, it is possible to reduce energy to be consumed by the temperature control mechanism 310 while efficiently performing temperature control on a predetermined target. In addition, it is possible to suppress consumption of the heat transfer gas.

A specific example of the temperature control mechanism 310 will now be described herein.

The temperature control mechanism 310 may include the heat transfer gas supplier 150 that controls supply of the heat transfer gas into the transfer chamber 140. The heat transfer gas supplier 150 controls, as the contents of temperature control, at least one of the temperature of the heat transfer gas to be supplied into the transfer chamber 140, presence or absence of supply of the heat transfer gas into the transfer chamber 140, and a flow rate of the heat transfer gas to be supplied into the transfer chamber 140. For example, increasing the temperature of the heat transfer gas to be supplied into the transfer chamber 140, starting supply of the heat transfer gas into the transfer chamber 140, and increasing the flow rate of the heat transfer gas to be supplied into the transfer chamber 140 make it possible to increase an output of temperature control. The heat transfer gas supplier 150 may supply the heat transfer gas toward a predetermined target in the transfer chamber 140 in at least a part of transfer in progress. As a result, it is possible to more efficiently control the temperature of the predetermined target. As the heat transfer gas, for example, it is possible to use an inert gas of nitrogen (N2), helium (He), neon (Ne), argon (Ar), or krypton (Kr), or hydrogen (H).

The temperature control mechanism 310 may include the gas exhaust system 160 configured to control exhaust of a gas in the transfer chamber 140. The gas exhaust system 160 is configured to control, as the contents of temperature control, at least one of presence or absence of exhaust and a flow rate of a gas to be exhausted from the transfer chamber 140. For example, starting exhaust of a gas in the transfer chamber 140 and increasing a flow rate of the heat transfer gas to be supplied into the transfer chamber 140 make it possible to increase an output of temperature control.

The temperature control mechanism 310 may include a heat medium supplier configured to control supply of a heat medium to an object that is subject to temperature control, which is provided in the transfer chamber 140. The heat medium supplier is at least one of a regulator for the temperature of the heat medium, an opening-and-closing valve provided in piping coupling the object and a supplier of the heat medium to the object, and a flow rate controller. The heat medium supplier controls, as the contents of temperature control, at least one of the temperature of the heat medium, presence or absence of supply of the heat medium, and the flow rate of the heat medium to be supplied to the object. For example, increasing a difference in temperature between a predetermined target and the heat medium, starting supply of the heat medium to the object, and increasing the flow rate of the heat medium to the object make it possible to increase an output of temperature control. An object to which the heat medium is to be supplied is an object that takes energy from an object serving as a predetermined target in the transfer chamber 140 or gives energy to an object serving as a predetermined target in the transfer chamber 140 through at least one of heat transfer and heat radiation. An object to which the heat medium is to be supplied is, for example, an object having a surface that easily absorbs electromagnetic waves, compared with other substances in a cooler, a lamp, and the transfer chamber 140 (a heat reflection suppressing body).

A configuration example of an object to which the heat medium is to be supplied and the heat medium supplier will now be described herein with reference to FIG. 2.

A cooler 801 serving as an object to which the heat medium is to be supplied is provided under a ceiling or on a bottom wall of the housing 141. In addition, the cooler 801 includes a refrigerant flow path 802 serving as piping, and is configured to allow a refrigerant serving as the heat medium to be supplied from the chiller 803 serving as a regulator of the temperature of the heat medium. Note herein that, as the refrigerant, for example, water (H2O) or perfluoropolyether (PFPE) is used. The chiller 803 may further include an opening-and-closing valve and an MFC serving as a flow rate controller. In addition, the refrigerant flow path 802 may be provided with an opening-and-closing valve and an MFC serving as a flow rate controller.

According to the present aspect, it is possible to acquire one or more effects as described below, in addition to the effects described above.

(a) Since it is possible to control the temperature of the wafer 200 during transfer, it is possible to shorten the period of time required for temperature control in the process chamber 201 serving as a destination of transfer. Therefore, it is possible to achieve an improvement in a number of the wafers 200 that are able to be processed per unit time (to improve a throughput).

(b) Since it is possible to control the contents of temperature control for a predetermined target in accordance with the contents of transfer, it is possible to reduce energy to be excessively consumed by the temperature control mechanism 310.

The embodiment of the present disclosure has been described above in detail, but the present disclosure is not limited to the embodiment described above, and various modified examples can be made without departing from the gist of the present disclosure.

In the above description, the example where cooling of a predetermined target is performed as temperature control has been described. However, the present disclosure is not limited to the example. Even when heating of a predetermined target is performed as temperature control, it is possible to acquire at least a part of the effects described above.

The foregoing embodiment has described an exemplary case where a film is formed using a single-type substrate processing apparatus configured to process one or several substrates at a time. However, the present disclosure is not limited to the foregoing embodiment. For example, the present disclosure is suitably applicable to a case where a film is formed using a batch-type substrate processing apparatus configured to process a plurality of substrates at a time. The foregoing embodiment has also described an exemplary case where a film is formed using a substrate processing apparatus including a cold wall-type processing furnace. However, the present disclosure is not limited to the foregoing embodiment. For example, the present disclosure is suitably applicable to a case where a film is formed using a substrate processing apparatus including a hot wall-type processing furnace.

Even in a case where such substrate processing apparatuses are each used, the corresponding processing can be performed in accordance with a processing procedure and processing conditions similar to those in the above-described embodiment, leading to obtainment of an effect similar to that in the above-described embodiment.

According to the present disclosure, it is possible to provide a technique capable of reducing energy excessively consumed by a substrate processing apparatus.

1. A substrate processing apparatus comprising:
a first process chamber in which processing of causing a temperature of a substrate to be a first temperature is performed;
a second process chamber in which processing of causing a temperature of the substrate to be a second temperature higher than the first temperature is performed;
a transfer chamber formed in communication with the first process chamber and the second process chamber and including a transfer mechanism configured to transfer the substrate;
a temperature control mechanism configured to perform temperature control on a predetermined target in the transfer chamber; and
a controller capable of controlling the transfer mechanism and the temperature control mechanism to perform:
control with contents of transfer of the substrate between the first process chamber and the second process chamber, and
control with contents of the temperature control in accordance with the contents of transfer to be performed.

2. The substrate processing apparatus according to claim 1, wherein:
the controller is further configured to control the transfer mechanism to perform the transfer so that the contents of the transfer include:
first transfer in which the substrate is transferred from the first process chamber to the second process chamber, and
second transfer in which the substrate is transferred from the second process chamber to the first process chamber, and
the controller is further configured to control the temperature control mechanism to perform the temperature control so that the contents of the temperature control include:
first temperature control that is to be performed in at least a part of the first transfer in progress, and
second temperature control that is to be performed in at least a part of the second transfer in progress and that is to be performed at an output different from an output of the first temperature control.

3. The substrate processing apparatus according to claim 2, wherein:
the temperature control mechanism cools the predetermined target, and
the controller is further configured to control the temperature control mechanism so that the second temperature control is performed at the output higher than the output of the first temperature control.

4. The substrate processing apparatus according to claim 3, wherein:
the controller is further configured to control the transfer mechanism so that the contents of the transfer further include presence or absence of the transfer in progress, and
the controller is further configured to control the temperature control mechanism so that the contents of the temperature control further include third temperature control that is to be performed in at least a part of a period of time in which the transfer in progress is not present and that is to be performed at an output lower than the output of the first temperature control.

5. The substrate processing apparatus according to claim 3, wherein:
the controller is further configured to control the transfer mechanism so that the contents of the transfer further include presence or absence of the transfer in progress, and
the controller is further configured to control the temperature control mechanism so that the contents of the temperature control further include:
fourth temperature control that is performed after the first transfer is ended and in at least a part of a period of time in which the transfer in progress is not present, and
fifth temperature control that is performed after the second transfer is ended and in at least a part of a period of time in which the transfer in progress is not present, and that is performed at an output higher than an output of the fourth temperature control.

6. The substrate processing apparatus according to claim 5, wherein:
the controller is further configured to control the temperature control mechanism so that the contents of the temperature control further include at least one selected from a group of:
sixth temperature control that is performed after the fourth temperature control is ended and in at least a part of a period of time in which the transfer in progress is not present, and that is performed at an output lower than the output of the fourth temperature control, or
seventh temperature control that is performed after the fifth temperature control is ended and in at least a part of a period of time in which the transfer in progress is not present, and that is to be performed at an output lower than the output of the fifth temperature control.

7. The substrate processing apparatus according to claim 1, wherein the controller is further configured to control the transfer mechanism so that the contents of the transfer include at least one selected from a group of a path along which the substrate moves in the transfer chamber in the transfer or a period of time taken for the transfer.

8. The substrate processing apparatus according to claim 1, wherein the temperature control mechanism performs temperature control on at least one selected from a group of the substrate, a gas in the transfer chamber, or an object in the transfer chamber as the predetermined target.

9. The substrate processing apparatus according to claim 1, further comprising a temperature measurer configured to measure a temperature of the predetermined target,
wherein the temperature control mechanism controls the contents of the temperature control in accordance with the temperature measured by the temperature measurer.

10. The substrate processing apparatus according to claim 1, wherein the first process chamber and the second process chamber are each configured to internally perform processing involving at least one selected from a group of a chemical reaction, supply of a gas in a plasma state, or adsorption of a process gas other than an inert gas on at least a part of the substrate.

11. The substrate processing apparatus according to claim 1, wherein the temperature control mechanism includes a heat transfer gas supplier configured to control supply of a heat transfer gas into the transfer chamber.

12. The substrate processing apparatus according to claim 11, wherein the heat transfer gas supplier controls, as the contents of the temperature control, at least one selected from a group of a temperature of the heat transfer gas, presence or absence of supply of the heat transfer gas into the transfer chamber, or a flow rate of the heat transfer gas to be supplied into the transfer chamber.

13. The substrate processing apparatus according to claim 11, wherein the heat transfer gas supplier supplies the heat transfer gas toward the predetermined target in the transfer chamber in at least a part of the transfer in progress.

14. The substrate processing apparatus according to claim 1, wherein the temperature control mechanism includes an exhaust system configured to control exhaust of a gas in the transfer chamber.

15. The substrate processing apparatus according to claim 14, wherein the exhaust system controls, as the contents of the temperature control, at least one selected from a group of presence or absence of the exhaust or a flow rate of a gas to be exhausted from the transfer chamber.

16. The substrate processing apparatus according to claim 1, wherein the temperature control mechanism includes a heat medium supplier configured to control supply of a heat medium to an object in the transfer chamber.

17. The substrate processing apparatus according to claim 16, wherein the heat medium supplier controls, as the contents of the temperature control, at least one selected from a group of a temperature of the heat medium, presence or absence of supply of the heat medium to the object, or a flow rate of the heat medium to be supplied to the object.

18. A method of processing a substrate, comprising:
(a) causing a temperature of the substrate in a first process chamber to be a first temperature;
(b) causing a temperature of the substrate in a second process chamber to be a second temperature higher than the first temperature;
(c) transferring the substrate between the first process chamber and the second process chamber via a transfer chamber; and
(d) performing temperature control on a predetermined target in the transfer chamber,
wherein contents of the temperature control are controlled in accordance with contents of the transfer.

19. The method of claim 18, further comprising manufacturing a semiconductor device.

20. A non-transitory computer-readable recording medium storing a program that causes, by a computer, a substrate processing apparatus to perform:
(a) causing a temperature of a substrate in a first process chamber to be a first temperature;
(b) causing a temperature of the substrate in a second process chamber to be a second temperature higher than the first temperature;
(c) transferring the substrate between the first process chamber and the second process chamber via a transfer chamber; and
(d) performing temperature control on a predetermined target in the transfer chamber,
wherein contents of the temperature control are controlled in accordance with contents of the transfer.
